(19) United States
(12) Patent Application Publication
(10) Pub. No.: US 2018/0053652 A1
(43) Pub. Date: Feb. 22, 2018

(54) METHOD OF FORMING AMORPHOUS SILICON LAYER

(71) Applicant: WONIK IPS CO., LTD., Gyeonggi-do (KR)

(72) Inventor: Young Chul CHOI, Gyeonggi-do (KR)

(21) Appl. No.: 15/473,895

(22) Filed: Mar. 30, 2017

(30) Foreign Application Priority Data
Aug. 19, 2016 (KR) 10-2016-0105666

(51) Int. Cl. H01L 21/033; H01L 21/02

(52) U.S. Cl. CPC H01L 21/0332; H01L 21/02532; H01L 21/02664; H01L 21/0262; H01L 21/0337; H01L 21/02592

(57) ABSTRACT

Provided is a method of forming an amorphous silicon layer. The method includes depositing an amorphous silicon layer on a substrate in a chamber; performing a post-treatment on an upper surface portion of the amorphous silicon layer using plasma by activating a post-treatment gas containing at least one component of nitrogen and oxygen groups, in order to improve the etch rate and surface roughness of the amorphous silicon layer; providing a purge gas to the chamber; and evacuating the chamber using a pump.

### CROSS-REFERENCE TO RELATED APPLICATIONS

This application claims priority to and the benefit of Korean Patent Application No. 10-2016-0105666 filed in the Korean Intellectual Property Office on Aug. 19, 2016, the entire contents of which are incorporated herein by reference.

### BACKGROUND

### Field

The present invention relates to a method of forming a material film, and more particularly, to a method of forming an amorphous silicon layer.

### Related Technology

In order to form fine patterns less than 10 nm by using an exposure equipment using an ArF laser (wavelength=193nm) without using an EUV exposure apparatus which is expensive, multi patterning process technologies such as Double Patterning Technology (DPT) or Quadruple Patterning Technology (QPT) have been proposed. A SiON film is used as a hard mask structure in this multi-patterning process and the etch selectivity ratio to the lower layer in the etching process is becoming an important issue as the fine patterning process needs to meet stricter requirements.

Such a method has been disclosed in Korean Patent Application Publication No. 2009-0114251 (published on Nov. 3, 2009, title of the invention: Method for forming fine patterns by spacer patterning technology)

### SUMMARY

The present invention has been made to solve a lot of problems including the above ones, by providing a method of forming an amorphous silicon layer capable of improving etch selectivity characteristics. However, these problems are for illustrative purposes only, and the scope of the present invention is not limited thereto.

There is provided a method of forming an amorphous silicon layer according to an aspect of the present invention in order to solve the above-described problems. The method includes depositing an amorphous silicon layer on a substrate in a chamber; performing a post-treatment on an upper surface portion of the amorphous silicon layer in the chamber by activating a post-treatment gas using plasma, the post-treatment gas containing at least one component of a nitrogen group and an oxygen group; providing a purge gas in the chamber; and evacuating the chamber.

In the method of forming an amorphous silicon layer, the performing a post-treatment may include performing a post-treatment on the amorphous silicon layer using the plasma by a post-treatment gas containing a nitrogen (N₂) and a nitrous oxide (N₂O) gas.

In the method of forming an amorphous silicon layer, the performing a post-treatment may include performing a post-treatment on the amorphous silicon layer using the plasma by a post-treatment gas containing a nitrous oxide (N₂O) gas.

In the method of forming an amorphous silicon layer, the performing a post-treatment may include forming a region containing relatively more components of at least one of nitrogen and oxygen groups on the upper surface portion of the amorphous silicon layer.

In the forming of the amorphous silicon layer, the depositing an amorphous silicon layer may include: providing a mono, di, or trisilane-based gas having the formula SiₓH_{y} as a reaction gas; and depositing an amorphous silicon layer by PECVD.

### ADVANTAGEOUS EFFECTS

According to the embodiments of the present invention as described above, it is possible to provide a method of forming an amorphous silicon layer capable of improving etch selectivity characteristics. Of course, the scope of the present invention is not limited by these effects.

### DESCRIPTION OF THE DRAWINGS

FIG. 1 is a flowchart illustrating a method of forming an amorphous silicon layer according to an embodiment of the present invention.

FIG. 2 is a graph comparing the results of measurement of the dry etch rate of amorphous silicon layers formed under different plasma post-treatment conditions according to the experimental examples of the present invention.

FIGS. 3 and 4 are diagrams comparing the results of measurement of surface roughness of amorphous silicon layers formed under different post-plasma treatment conditions according to experimental examples of the present invention.

FIGS. 5 to 8 show the results of TOF-SIMS measurement of the components of each amorphous silicon layer of Experimental Example 1, Experimental Example 2 and Experimental Example 5 of Table 1.

### DETAILED DESCRIPTION

Hereinafter, embodiments of the present invention will be described in detail with reference to the accompanying drawings. In the specification, it will be understood that when an element, such as a layer, region, or substrate, is referred to as being “on,” “connected to,” “stacked on” or “coupled to” another element, it can be directly “on,” “connected to,” “stacked on” or “coupled to” the other element or intervening elements may be present. In contrast, when an element is referred to as being “directly on,” “directly connected to” or “directly coupled to” another element, there are no intervening elements present.

In the drawings, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Furthermore, the thickness and size of each layer in the drawings may be exaggerated for convenience and clarity of explanation. Like numerals refer to like elements.

The plasma referred to in the present invention may be generated by a direct plasma process. In the direct plasma process, for example, a pretreatment gas, a reaction gas, and/or a post-treatment gas are supplied to the processing space between the electrode and the substrate and then a frequency power is applied such that a plasma of the pretreatment gas, reaction gas, and/or post-treatment gas is formed directly in the processing space inside the chamber.

For convenience of explanation, in the present invention, a state in which a specific gas is activated using plasma is referred to as a ‘specific gas plasma’. For example, a state in which ammonia (NH₃) gas is activated using plasma is referred to as an ammonia (NH₃) plasma, a state in which ammonia (NH₃) gas and nitrogen (N₂) gas are activated together by plasma is referred to as an ammonia (NH₃) and nitrogen (N₂) plasma, and a state in which nitrous oxide (N₂O) gas and nitrogen (N₂) gas are activated together using plasma is referred to as a nitrous oxide (N₂O) and nitrogen (N₂) plasma.

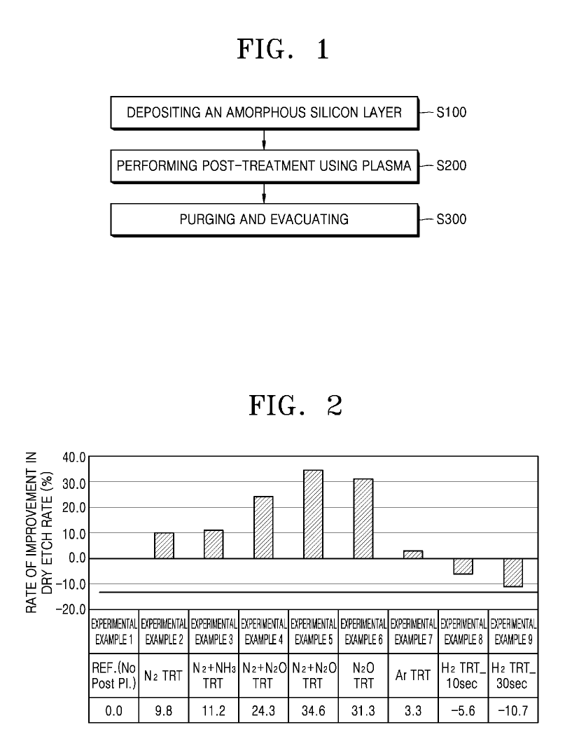

FIG. 1 is a flowchart illustrating a method of forming an amorphous silicon layer according to an embodiment of the present invention.

Referring to FIG. 1, a method of forming an amorphous silicon layer according to an embodiment of the present invention includes depositing an amorphous silicon layer on a substrate in a chamber (S100); performing a post-treatment using plasma containing at least one of a nitrogen group and an oxygen group on the upper surface portion of the amorphous silicon layer (S200); and purging the chamber by supplying a purge gas to the chamber and evacuating the chamber (S300).

The step (S100) of depositing an amorphous silicon layer on the substrate may include depositing an amorphous silicon layer on a lower layer formed on the substrate by supplying a reaction gas and an inert gas onto the substrate in the chamber and applying a high frequency power to generate plasma. In the step (S100) of depositing an amorphous silicon layer, if a low frequency power is applied to generate plasma, part of the amorphous silicon layer may be formed as a powder, which may result in poor film quality. The high frequency power and the low frequency power referred to in the present invention are applied as power to generate plasma in the chamber and can be relatively divided based on the frequency range of the RF power. For example, the high frequency power has a frequency range from 3 MHz to 30 MHz, and preferably from 13.56 MHz to 27.12 MHz. The low frequency power has a frequency range from 30 KHz to 3,000 KHz and preferably from 300 KHz to 600 KHz.

The lower layer may include an oxide layer, an oxynitride layer, or a nitride layer. In addition, the lower layer may include an SOH layer which is used as a hard mask in a photolithography process.

The reaction gas may include a mono, di, or trisilane-based reaction gas having the formula SiₓH_{y}. For example, the reaction gas may include a silane (SiH₄) gas. The inert gas may include at least one selected from helium (He), neon (Ne) and argon (Ar). The inert gas may include, for example, an argon gas.

The step (S100) of depositing an amorphous silicon layer may be, for example, a plasma enhanced chemical vapor deposition (PECVD) process. In a chemical vapor deposition (CVD) process, a reaction gas is injected close to a substrate in a chamber and then the reaction gas reacts on a surface of the target to form a thin film on the surface of target and reaction by-products after the deposition process are removed from the chamber. In the case of applying heat as the energy required for the reaction of the reaction gas, a temperature of 500° C. to 1000° C. or more may be required. However, such a deposition temperature may have an undesirable influence on the peripheral components. For this reason, a method of forming an amorphous silicon layer according to an embodiment of the present invention may employ in the deposition step (S100) a plasma enhanced chemical vapor deposition process, which ionizes at least part of a reaction gas and is one of the methods utilized in a CVD process for reducing a reaction temperature.

However, the technical idea of the present invention is not limited thereto, and the step (S100) of depositing an amorphous silicon layer may be applied to cases where the step of depositing an amorphous silicon layer includes an atomic layer deposition (ALD) process.

A method of forming an amorphous silicon layer according to another embodiment of the present invention may include the step of stabilizing gases in the chamber before the step (S100) of depositing an amorphous silicon layer, wherein the reaction gas and the inert gas are supplied onto the substrate in the chamber while the power for generating plasma is not applied.

A method of forming an amorphous silicon layer according to a modified embodiment of the present invention may further include the step of performing a pretreatment step performing an ammonia (NH₃) plasma treatment on the lower layer before the step (S100) of depositing an amorphous silicon layer. By performing the plasma pretreatment on the lower layer, the subsequent amorphous silicon layer can be smoothly deposited, such that a good surface roughness is provided on the amorphous silicon layer, the bonding force between the lower layer and the amorphous silicon layer is strengthened and the thickness uniformity of the amorphous silicon layer is improved. The power applied to generate the ammonia (NH₃) plasma in the pretreatment step may be a dual frequency power comprising a low frequency power and a high frequency power. When the sum of the low frequency power and the high frequency power is less than 900 W, hydrogen groups in the lower layer are not removed and dangling bonds are not generated, such that silicon atoms are not effectively bonded to the lower layer. The dual frequency power applied to generate the ammonia (NH₃) plasma in the pretreatment step is preferably 900 W or more.

The step (S200) of performing a post-treatment may include the step of performing a surface treatment on the upper surface portion of the amorphous silicon layer using plasma containing at least one of a nitrogen group and an oxygen group.

The plasma containing at least one of a nitrogen group and an oxygen group may comprise a nitrous oxide (N₂O) plasma, a nitrogen monoxide (NO) plasma, an ammonia (NH₃) plasma and a nitrogen (N₂) plasma, or a combination thereof. For example, the plasma containing at least one of a nitrogen group and an oxygen group may be a nitrogen (N₂) and nitrous oxide (N₂O) plasma, a nitrous oxide (N₂O) plasma, a nitrogen (N₂) plasma, or may include a nitrogen (N₂) and ammonia (NH₃) plasma.

According to an embodiment of the present invention, after the amorphous silicon layer used as a hard mask layer is deposited using PECVD, the above-described post-treatment step is performed to effectively remove the hydrogen group from the upper interface of the amorphous silicon layer and form an interfacial protective layer, thereby improving the dry etch rate characteristic in the subsequent dry process. The post-treatment gas may include nitrous oxide (N₂O) and/or nitrogen monoxide (NO), which is capable of effecting oxidization on the upper interface of the amorphous silicon layer by adding an oxygen group. Furthermore, the post-treatment gas may include ammonia (NH₃) and/or nitrogen (N₂), which is capable of effecting nitridation on the upper interface of the amorphous silicon layer by adding a nitrogen group.

After performing the step (S100) of depositing an amorphous silicon layer and the step (S200) of performing a post-treatment, the step (S300) of purging the chamber by supplying a purge gas to the chamber and evacuating the chamber using a pump is performed. The step (S100) of depositing an amorphous silicon layer and the step (S200) of performing a post-treatment proceed in-situ by being successively performed without evacuating the chamber inbetween.

A hard mask structure for performing a photolithography process on the substrate can be prepared by performing the step (S100) of depositing an amorphous silicon layer and the step (S200) of performing a post-treatment. When a SiON film, which can be used as a hard mask structure in a multi-patterning process such as Double Patterning Technology (DPT) or Quadruple Patterning Technology (QPT) is replaced with an amorphous silicon layer prepared by the above-described method, the etch selectivity ratio to the lower layer becomes more excellent. A description thereof will be provided later with reference to experimental examples.

Hereinafter, the technical idea of the present invention will be illustratively explained by comparing the characteristics of film quality realized in the methods of forming an amorphous silicon layer according to various experimental examples of the present invention.

Table 1 compares the characteristics of an amorphous silicon layer formed under different plasma post-treatment conditions according to the experimental examples of the present invention.

TABLE 1

| | | | | Roughness | | Dry etch rate | | |
|---|---|---|---|---|---|---|---|---|
| | | | | | Rate of | Rate of | Deposition | |
| Film | | | Unif | | improvement | improvement | rate | R.I |
| quality | Subsequent plasma condition | | (%) | (Å) | (%) | (%) | (Å/min) | (560 nm) |
| SiON | Experimental | N₂O_10000 sccm | — | 0.90 | — | — | — | — |
| | Example 10 | | | | | | | |
| a-Si | Experimental | X | 0.38 | 8 | 0.0 | 0.0 | 1115 | 4.5 |
| | Example 1 | | | | | | | |
| | Experimental | N_{2—}10000 sccm | 0.34 | 8.1 | −1.2 | 9.8 | 1098 | 4.5 |
| | Example 2 | | | | | | | |
| | Experimental | N_{2—}9500 sccm/ | 0.34 | 8.3 | −3.6 | 11.2 | 1100 | 4.5 |
| | Example 3 | NH_{3—}500 sccm | | | | | | |
| | Experimental | N_{2—}9500 sccm/ | 0.34 | 7.9 | 1.3 | 24.3 | 1090 | 4.5 |
| | Example 4 | N₂O_500 sccm | | | | | | |
| | Experimental | N_{2—}5000 sccm/ | 0.33 | 4.1 | 95.1 | 34.6 | 1089 | 4.5 |
| | Example 5 | N₂O_5000 sccm | | | | | | |
| | Experimental | N₂O_10000 sccm | 0.3 | 2.9 | 175.9 | 31.3 | 1091 | 4.5 |
| | Example 6 | | | | | | | |
| | Experimental | Ar_10000 sccm | 0.38 | 7.9 | 1.3 | 3.3 | 1111 | 4.5 |
| | Example 7 | | | | | | | |
| | Experimental | H_{2—}10000 sccm | 0.41 | 13.2 | −39.4 | −5.6 | 1103 | 4.5 |
| | Example 8 | | | | | | | |
| | Experimental | H_{2—}10000 sccm | 0.38 | 9.7 | −17.5 | −10.7 | 1096 | 4.5 |
| | Example 9 | | | | | | | |

Referring to Table 1, the rate of improvement in dry etch rate represents the ratio of the dry etch rate of the amorphous silicon layer to the dry etch rate of the SiON film.

Experimental Example 1 corresponds to the case where an amorphous silicon layer is deposited and no additional plasma post-treatment is performed.

Experimental Example 2 corresponds to the case where an amorphous silicon layer is deposited and then a nitrogen (N₂) gas is supplied at a flow rate of 10,000 sccm to the chamber, and then a high frequency power is applied to generate plasma, thereby performing a post-treatment.

Experimental Example 3 corresponds to the case where an amorphous silicon layer is deposited and then nitrogen (N₂) and ammonia (NH₃) gases are supplied at a flow rate of 9,500 sccm and 500 sccm, respectively, to the chamber, and then a high frequency power is applied to generate plasma, thereby performing a post-treatment.

Experimental Example 4 corresponds to the case where an amorphous silicon layer is deposited and then nitrogen (N₂) and nitrous oxide (N₂O) gases are supplied at a flow rate of 9,500 sccm and 500 sccm, respectively, to the chamber, and then a high frequency power is applied to generate plasma, thereby performing a post-treatment.

Experimental Example 5 corresponds to the case where an amorphous silicon layer is deposited and then nitrogen (N₂) and nitrous oxide (N₂O) gases are supplied at a flow rate of 5,000 sccm and 5,000 sccm, respectively, to the chamber, and then a high frequency power is applied to generate plasma, thereby performing a post-treatment.

Experimental Example 6 corresponds to the case where an amorphous silicon layer is deposited and then a nitrous oxide (N₂O) gas is supplied at a flow rate of 10,000 sccm to the chamber, and then a high frequency power is applied to generate plasma, thereby performing a post-treatment.

Experimental Example 7 corresponds to the case where an amorphous silicon layer is deposited and then an argon (Ar) gas is supplied at a flow rate of 10,000 sccm to the chamber, and then a high frequency power is applied to generate plasma, thereby performing a post-treatment.

Experimental Example 8 corresponds to the case where an amorphous silicon layer is deposited and then a hydrogen (H₂) gas is supplied at a flow rate of 10,000 sccm to the chamber, and then a high frequency power is applied to generate plasma, thereby performing a post-treatment for 10 seconds.

Experimental Example 9 corresponds to the case where an amorphous silicon layer is deposited and then a hydrogen (H₂) gas is supplied at a flow rate of 10,000 sccm to the chamber, and then a high frequency power is applied to generate plasma, thereby performing a post-treatment for 30 seconds.

Meanwhile, Experimental example 10 corresponds to the case where a SiON film is deposited and then a nitrous oxide (N₂O) gas is supplied at a flow rate of 10,000 sccm to the chamber, and then a high frequency power is applied to generate plasma, thereby performing a post-treatment.

Referring to the experimental examples on Table 1, Experimental Example 5 is an example that satisfies both the requirement of improving the dry etch rate and the requirement of improving the surface roughness. Experimental Example 6 is preferable in terms of surface roughness, but the dry etch rate is lower than Experimental Example 5. Therefore, it is possible to selectively apply Experimental Example 5 and Experimental Example 6, when necessary.

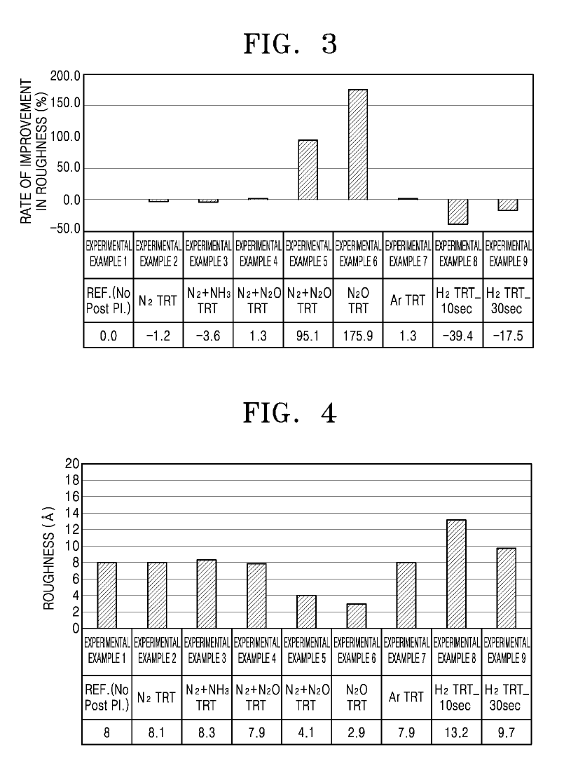

FIG. 2 is a graph comparing the results of measurement of the dry etch rate of amorphous silicon layers formed under different plasma post-treatment conditions according to the experimental examples of the present invention. Referring to Table 1 and FIG. 2, when the amorphous silicon layer is subjected to a post-treatment using a nitrous oxide (N₂O) plasma (Experimental Examples 5 and 6), the film quality of the amorphous silicon layer is more than 30% harder than when no post-treatment is performed to the amorphous silicon layer (Experimental Example 1). Thus, it is confirmed that the etch selectivity characteristics improved.

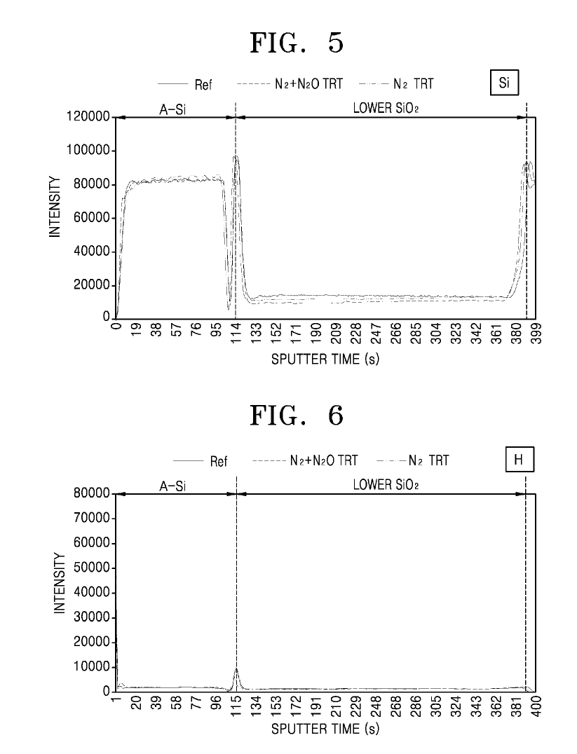

FIGS. 3 and 4 are diagrams comparing the results of measurement of surface roughness of amorphous silicon layers formed under different post-plasma treatment conditions according to experimental examples of the present invention. Referring to Table 1, FIG. 3, and FIG. 4, when a post-treatment is performed to the amorphous silicon layer using a nitrous oxide (N₂O) plasma (Experimental Examples 5 and 6), the surface roughness of the amorphous silicon layer improved by 100% or more than when no post-treatment is performed to the amorphous silicon layer (Experimental Example 1).

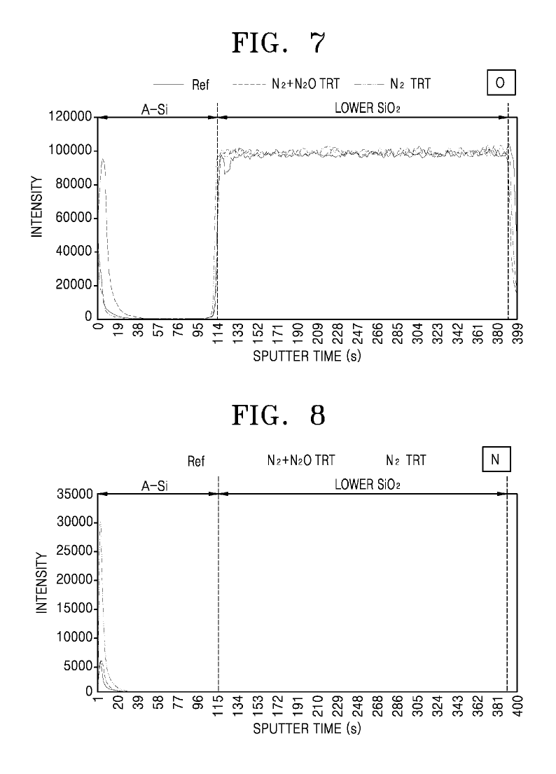

FIGS. 5 to 8 show the results of TOF-SIMS measurement of the components of each amorphous silicon layer of Experimental Example 1, Experimental Example 2 and Experimental Example 5 of Table 1.

Referring to FIG. 5, the composition profiles of the silicon (Si) component in the amorphous silicon layer and the silicon oxide layer, which is as the lower layer, did not show any significant differences in Experimental Example 1 (Ref), Experimental Example 2 (N₂ TRT) and Experimental Example 5 (N₂+N₂O TRT).

Referring to FIG. 6, the composition profiles of the hydrogen (H) component in the amorphous silicon layer and the silicon oxide layer, which is as the lower layer, did not show any significant differences in Experimental Example 1 (Ref), Experimental Example 2 (N₂ TRT) and Experimental Example 5 (N₂+N₂O TRT).

Referring to FIG. 7, the composition profile of the oxygen (O) component in the amorphous silicon layer and the silicon oxide layer, which is the lower layer, showed a significant difference in Experimental Example 5 (N₂+N₂O TRT) compared with Experimental Example 1 (Ref). That is, it was confirmed that a large amount of oxygen component was contained in the upper surface portion of the amorphous silicon layer in the case where an amorphous silicon layer was deposited and then nitrogen (N₂) and nitrous oxide (N₂O) gases were supplied to the chamber and then a high frequency power was applied to generate plasma, thereby performing a post-treatment (Experimental Example 5) compared with the case where no additional post-plasma treatment was performed after the amorphous silicon layer was deposited (Experimental Example 1).

Referring to FIG. 8, the composition profile of the nitrogen (N) component in the amorphous silicon layer and the silicon oxide layer, which is the lower layer, showed a significant difference in Experimental Example 2 (N₂ TRT) compared with Experimental Example 1 (Ref). That is, it was confirmed that a large amount of nitrogen component was contained in the upper surface portion of the amorphous silicon layer in the case where an amorphous silicon layer was deposited and then a nitrogen (N₂) gas was supplied to the chamber, and then a high frequency power was applied to generate plasma, thereby performing a post-treatment (Experimental Example 2) compared with the case where no additional post-plasma treatment was performed after the amorphous silicon layer was deposited (Experimental Example 1).

Accordingly, it was confirmed that a nitrogen (N₂) as a post-treatment gas effected nitridation in the upper interface of the amorphous silicon layer by adding a nitrogen group, and a nitrous oxide (N₂O) gas as a post-treatment gas effected oxidation in the upper interface of the amorphous silicon layer by adding an oxygen group. Furthermore, it was confirmed that, by performing the post-treatment, a region containing relatively more components of at least one of nitrogen and oxygen groups was formed on the upper surface portion of the amorphous silicon layer.

While the present invention has been particularly shown and described with reference to embodiments shown in the drawings, it is only for illustrative purposes. It will be understood by those skilled in the art that various modifications and equivalent embodiments may be made. Therefore, the scope of the present invention should be determined by the technical idea of the appended claims.

1. A method of forming an amorphous silicon layer, the method comprising:
depositing an amorphous silicon layer on a substrate in a chamber;
performing a post-treatment on an upper surface portion of the amorphous silicon layer in the chamber by activating a post-treatment gas using plasma, the post-treatment gas containing at least one component of a nitrogen group and an oxygen group;
providing a purge gas in the chamber; and
evacuating the chamber using a pump.

2. The method of claim 1,
wherein the performing a post-treatment comprises performing a post-treatment on the amorphous silicon layer using the plasma by a post-treatment gas containing a nitrogen (N₂) and a nitrous oxide (N₂O) gas.

3. The method of claim 1,
wherein the performing a post-treatment comprises performing a post-treatment on the amorphous silicon layer using the plasma by a post-treatment gas containing a nitrous oxide (N₂O) gas.

4. The method of claim 1,
wherein the performing a post-treatment comprises forming a region containing relatively more components of at least one of nitrogen and oxygen groups on the upper surface portion of the amorphous silicon layer.

5. The method of claim 1,
wherein the depositing an amorphous silicon layer comprises:
providing a mono, di, or trisilane-based gas having the formula SiₓH_{y} as a reaction gas; and
depositing an amorphous silicon layer by PECVD.
